(19) United States
(12) Patent Application Publication
(10) Pub. No.: US 2026/0324202 A1
(43) Pub. Date: Oct. 15, 2026

(54) DISPLAY DEVICE

(71) Applicant: LG Display Co., Ltd., Seoul (KR)

(72) Inventors: Jaesung KIM, Paju-si (KR); Sohyun KIM, Paju-si (KR); DongSoo KIM, Paju-si (KR); Taehwi KIM, Paju-si (KR)

(73) Assignee: LG Display Co., Ltd., Seoul (KR)

(21) Appl. No.: 19/461,348

(22) Filed: Jan. 27, 2026

(30) Foreign Application Priority Data
Feb. 28, 2025 (KR) 10-2025-0026685

(51) Int. Cl. H10K 59/122; H10H 29/37; H10H 29/85; H10H 29/854; H10H 29/855; H10K 59/38; H10K 59/80; H10K 102/00

(52) U.S. Cl. CPC H10K 59/122; H10H 29/37; H10H 29/8517; H10H 29/854; H10H 29/8552; H10K 59/38; H10K 59/8731; H10K 59/8792; H10K 2102/351

(57) ABSTRACT

A display device can include a substrate, a pixel electrode disposed on the substrate, a first bank disposed on the pixel electrode, a second bank disposed on the first bank, an encapsulation layer disposed on the second bank, and a color filter disposed on the encapsulation layer. The first bank can include a plurality of first holes overlapping the pixel electrode, and the second bank can include a plurality of second holes overlapping the plurality of first holes, and a fine region not overlapping the plurality of first holes.

### CROSS-REFERENCE TO RELATED APPLICATION

This application claims priority to Korean Patent Application No. 10-2025-0026685, filed in the Republic of Korea on Feb. 28, 2025, which is hereby expressly incorporated by reference for all purposes as if fully set forth herein.

### BACKGROUND

### Field

Embodiments of the present disclosure relate to a device and particularly to, for example, without limitation, a display device.

### Discussion of the Related Art

A display device is applied to various electronic devices such as TVs, mobile phones, laptops, and tablets. The display device can include an organic light emitting display (OLED: Organic Light Emitting Display) that emits light by itself, or a liquid crystal display (LCD: Liquid Crystal Display) that requires a separate light source.

A light-emitting device includes an anode, an organic light-emitting layer, and a cathode, but the organic light-emitting layer can be vulnerable to oxygen and/or moisture. Accordingly, an encapsulation layer can be disposed on the light-emitting device to protect the light-emitting device from physical impact and oxygen and/or moisture.

### SUMMARY OF THE DISCLOSURE

Embodiments of the present disclosure can provide a display device having improved viewing angle characteristics.

Embodiments of the present disclosure can provide a display device having an encapsulation layer capable of securing reliability with high spreadability.

The objects of the embodiments of the present disclosure are not limited to those mentioned herein, and other objects not mentioned will be clearly understood by those skilled in the art from the following description.

A display device according to embodiments of the present disclosure can include a substrate, a pixel electrode disposed on the substrate, a first bank disposed on the pixel electrode, a second bank disposed on the first bank, an encapsulation layer disposed on the second bank, and a color filter disposed on the encapsulation layer, wherein the first bank comprises a plurality of first holes overlapping the pixel electrode, and wherein the second bank comprises a plurality of second holes overlapping the plurality of first holes, and a fine region not overlapping the plurality of first holes.

According to embodiments of the present disclosure, it is possible to provide a display device having improved viewing angle characteristics.

According to embodiments of the present disclosure, it is possible to provide a display device having an encapsulation layer capable of securing reliability with high spreadability.

According to embodiments of the present disclosure, it is possible to contribute to weight reduction of a display panel by reducing the thickness of the encapsulation layer.

The effects of the embodiments of the present disclosure are not limited to those described above, and other effects not mentioned will be clearly understood by those skilled in the art from the description of the claims.

### BRIEF DESCRIPTION OF THE DRAWINGS

The present disclosure will be more fully understood from the detailed description given below and the accompanying drawings, which are provided for illustrative purposes only and are not intended to limit the scope of the present disclosure.

FIG. 1 is a system configuration diagram of a display device according to embodiments of the present disclosure.

FIG. 2 illustrates a display device according to embodiments of the present disclosure.

FIGS. 3 to 5 illustrate examples of a display panel according to embodiments of the present disclosure.

FIG. 6 is a cross-sectional view of the display panel of FIG. 3 taken along lines A-A’ and B-B’ according to embodiments of the present disclosure.

FIG. 7 is a cross-sectional view of the display panel of FIG. 3 taken along line A-A’ according to embodiments of the present disclosure.

FIG. 8 is a cross-sectional view of the display panel of FIG. 3 taken along line B-B’ according to embodiments of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description can make the subject matter in some embodiments of the present disclosure rather unclear. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Any implementation described herein as an “example” is not necessarily to be construed as preferred or advantageous over other implementations.

In the description of the various embodiments of the present disclosure, where positional relationships are described, for example, when a position relation between two parts is described as, for example, “on,” “over,” “above,” “under,” “below,” “adjacent,” and “next,” or the like, one or more other parts can be located between the two parts unless a more limiting term, such as “just” or “direct(ly)” is used. For example, where an element or layer is disposed “on” another element or layer, a third layer or element can be interposed therebetween.

Terms, such as “first”, “second”, “A”, “B”, “(A)”, or “(B)” can be used herein to describe elements of the present disclosure. Each of these terms is not used to define essence, order, sequence, or number of elements etc., but is used merely to distinguish the corresponding element from other elements.

When it is mentioned that a first element "is connected or coupled to", “contacts or overlaps” etc. a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc. each other via a fourth element. Here, the second element can be included in at least one of two or more elements that "are connected or coupled to", “contact or overlap”, etc. each other.

When time relative terms, such as "after," "subsequent to," "next," "before," and the like, are used to describe processes or operations of elements or configurations, or flows or steps in operating, processing, manufacturing methods, these terms can be used to describe non-consecutive or non-sequential processes or operations unless the term "directly" or "immediately" is used together.

In addition, when any dimensions, relative sizes etc. are mentioned, it should be considered that numerical values for elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term such as “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Rather, these embodiments can be provided so that this disclosure can be sufficiently thorough and complete to assist those skilled in the art to fully understand the scope of the present disclosure. Furthermore, the present disclosure is only defined by scopes of claims.

Features of various embodiments of the present disclosure can be partially or overall coupled to or combined with each other, and can be variously inter-operated with each other and driven technically as those skilled in the art can sufficiently understand. Embodiments of the present disclosure can be carried out independently from each other, or can be carried out together in co-dependent relationship.

Hereinafter, various embodiments of the present disclosure will be described in detail with reference to the accompanying drawings. All the components of each display device according to all embodiments of the present disclosure are operatively coupled and configured.

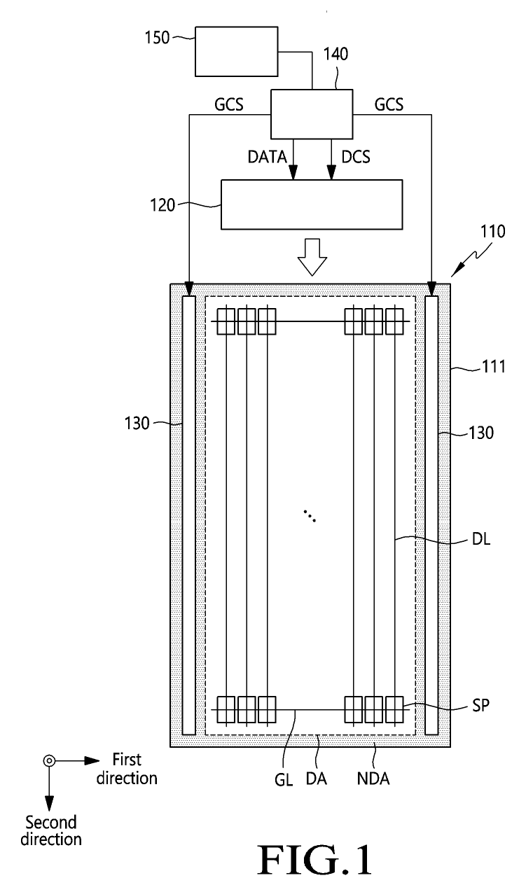

FIG. 1 illustrates a display device 100 according to embodiments of the present disclosure.

Referring to FIG. 1, the display device 100 according to embodiments of the present disclosure can include, as components for image display, a display panel 110 and a display driving circuit. The display driving circuit can be a circuit for driving the display panel 110. The display driving circuit can include a data driving circuit 120, a gate driving circuit 130, and a controller 140, but embodiments of the present disclosure are not limited thereto.

The display panel 110 can include a substrate 111 and a plurality of sub-pixels SP disposed on the substrate 111.

The substrate 111 can include a display area DA and a non-display area NDA.

The display area DA can be an area capable of image display and can also be referred to as an active area. A plurality of sub-pixels SP for image display can be disposed in the display area DA. The non-display area NDA can be an area where image display is not performed and can be an outer area of the display area DA. The non-display area NDA can also be referred to as a bezel (or bezel area). The non-display area NDA can include a pad area (also referred to as a pad portion).

For example, the non-display area NDA can include a first non-display area around the periphery of the display area DA, a second non-display area including the pad area, and a bending area between the first non-display area and the second non-display area.

A driving circuit can be connected to or bonded (or attached) to the pad area. Depending on the bending of the bending area, the bending area and the second non-display area can be disposed behind the first non-display area so as not to be visible from the front. The first non-display area can have a very small size. Embodiments of the present disclosure are not limited thereto.

When a user views the display device 100 from the front, the non-display area NDA visible to the user can be almost none or may not exist at all, but embodiments of the present disclosure are not limited thereto.

The display device 100 according to embodiments of the present disclosure can be a self-emissive display device in which the display panel 110 emits light by itself, but embodiments of the present disclosure are not limited thereto. In the case where the display device 100 according to embodiments of the present disclosure is a self-emissive display device, each of the plurality of sub-pixels SP can include a light-emitting device.

For example, the display device 100 according to embodiments of the present disclosure can be an organic light emitting display device implemented with a light-emitting device that is an organic light emitting diode (OLED: Organic Light Emitting Diode). In another example, the display device 100 according to embodiments of the present disclosure can be an inorganic light emitting display device implemented with a light-emitting device that is an inorganic-based light emitting diode. In another example, the display device 100 according to embodiments of the present disclosure can be a quantum dot display device implemented with a light-emitting device that is a quantum dot, which is a semiconductor crystal that emits light by itself. In another example, the display device 100 according to embodiments of the present disclosure can be a micro LED display device or a mini LED display device.

The structure of each of the plurality of sub-pixels SP can vary depending on the type of the display device 100. For example, in the case where the display device 100 is a self-emissive display device in which the sub-pixels SP emit light by themselves, each sub-pixel SP can include a light-emitting device that emits light by itself, one or more transistors, and one or more capacitors, but embodiments of the present disclosure are not limited thereto.

Various types of signal lines for driving the plurality of sub-pixels SP can be disposed on the substrate 111 of the display panel 110. For example, the various types of signal lines can include a plurality of data lines DL for delivering data signals (also referred to as data voltages or image signals) to the plurality of sub-pixels SP, and a plurality of gate lines GL for delivering gate signals (also referred to as scan signals) to the plurality of sub-pixels SP.

For example, the plurality of data lines DL and the plurality of gate lines GL can intersect each other. Each of the plurality of gate lines GL can be disposed to extend in a first direction (for example, a row direction or a column direction). Each of the plurality of data lines DL can be disposed to extend in a second direction (for example, a column direction or a row direction) different from the first direction.

In embodiments of the present disclosure, the angle formed between the first direction and the second direction can be perpendicular (or 90 degrees) or can be an angle different from perpendicular.

The data driving circuit 120 can be a circuit for driving the plurality of data lines DL and can output data signals to the plurality of data lines DL.

The data driving circuit 120 can receive image data DATA in a digital form from the controller 140, convert the received image data DATA into data signals in an analog form (also referred to as data voltages), and output the data signals to the plurality of data lines DL.

In the display device 100 according to embodiments of the present disclosure, the gate driving circuit 130 can be embedded in the display panel 110 in a gate-in-panel (GIP) type, but embodiments of the present disclosure are not limited thereto.

The gate driving circuit 130 can include a plurality of transistors. Each of the plurality of transistors included in the gate driving circuit 130 can include an active layer including a first semiconductor material, and each of the plurality of transistors included in the sub-pixels SP can include an active layer including a second semiconductor material. In one example, the first semiconductor material and the second semiconductor material can be substantially the same. In another example, the first semiconductor material and the second semiconductor material can be different from each other. For example, the first semiconductor material can be a silicon-based semiconductor material (e.g., LTPS (Low Temperature Poly Silicon)), and the second semiconductor material can be an oxide semiconductor material. For example, the active layer can be a semiconductor layer, but is not limited thereto.

The controller 140 can be a device for controlling the data driving circuit 120 and the gate driving circuit 130 and can control driving timings for the plurality of data lines DL and driving timings for the plurality of gate lines GL.

The controller 140 can receive input image data from a host system 150 and can supply the image data DATA to the data driving circuit 120 based on the input image data.

The display device 100 according to embodiments of the present disclosure can be a mobile terminal such as a smartphone or a tablet, a monitor or a television (TV) of various sizes, or various types and sizes of displays capable of displaying information or images, without being limited thereto.

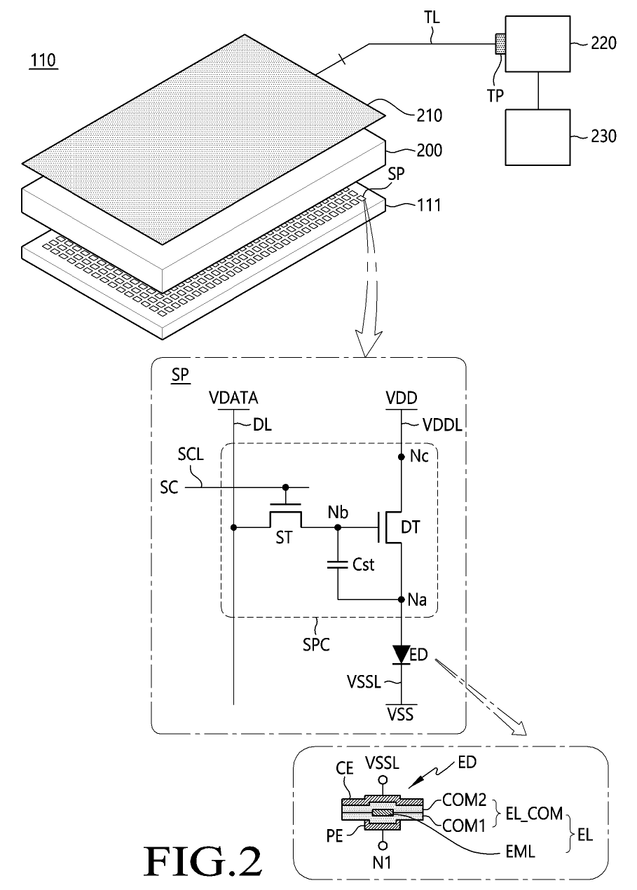

FIG. 2 illustrates an example of the display panel 110 according to embodiments of the present disclosure.

Referring to FIG. 2, the display panel 110 according to embodiments of the present disclosure can include the substrate 111 on which the plurality of sub-pixels SP are disposed, and an encapsulation layer 200 on the substrate 111. The encapsulation layer 200 can also be referred to as an encapsulation substrate or encapsulation portion.

When the display device 100 according to embodiments of the present disclosure is a self-emissive display device, each of the plurality of sub-pixels SP disposed on the substrate 111 can include a light-emitting device ED and a sub-pixel circuit SPC for driving the light-emitting device ED.

The sub-pixel circuit SPC can include a plurality of transistors for driving the light-emitting device ED and at least one capacitor; however, the embodiments of the present disclosure are not limited thereto. In the present disclosure, the sub-pixel circuit SPC can drive the light-emitting device ED by supplying a driving current to the light-emitting device ED at a predetermined timing. The light-emitting device ED can be driven by the driving current to emit light.

The plurality of transistors can include a driving transistor DT for driving the light-emitting device ED and a scan transistor ST that is turned on or off according to a scan signal SC.

The driving transistor DT can supply the driving current to the light-emitting device ED. The scan transistor ST can be configured to control an electrical state of a corresponding node in the sub-pixel circuit SPC, or to control a state or operation of the driving transistor DT. The at least one capacitor can include a storage capacitor Cst for maintaining a constant voltage during a frame.

For driving the sub-pixel SP, a data signal VDATA, which is a video signal, and a scan signal SC, which is one type of gate signal, can be applied to the sub-pixel SP. In addition, for driving the sub-pixel SP, a common driving signal including a driving voltage VDD and a ground voltage VSS can be applied to the sub-pixel SP.

The light-emitting device ED can include a pixel electrode PE, a light-emitting layer EL, and a common electrode CE. The light-emitting layer EL can be disposed between the pixel electrode PE and the common electrode CE.

For example, the pixel electrode PE can be an electrode disposed in each sub-pixel SP, and the common electrode CE can be an electrode disposed in common to the plurality of sub-pixels SP. In one example, the pixel electrode PE can be an anode, and the common electrode CE can be a cathode. In another example, the pixel electrode PE can be a cathode, and the common electrode CE can be an anode. Hereinafter, for convenience of explanation, the case where the pixel electrode PE is an anode and the common electrode CE is a cathode will be described as an example.

When the light-emitting device ED is an organic light-emitting device, the light-emitting layer EL can include an intermediate emission layer EML, a first common intermediate layer COM1 between the pixel electrode PE and the intermediate emission layer EML, and a second common intermediate layer COM2 between the intermediate emission layer EML and the common electrode CE. The first common intermediate layer COM1 and the second common intermediate layer COM2 can be collectively referred to as a common intermediate layer EL_COM.

The intermediate emission layer EML can be disposed in each sub-pixel SP or commonly disposed across a plurality of sub-pixels SP. The common intermediate layer EL_COM can be commonly disposed across a plurality of sub-pixels SP; however, the embodiments of the present disclosure are not limited thereto.

For example, the intermediate emission layer EML can be disposed in each emission area or commonly disposed across a plurality of emission areas. The common intermediate layer EL_COM can be commonly disposed across a plurality of emission areas and non-emission areas; however, the embodiments of the present disclosure are not limited thereto.

For example, the first common intermediate layer COM1 can include a hole injection layer HIL, an electron blocking layer EBL, and a hole transport layer HTL, among others; however, the embodiments of the present disclosure are not limited thereto. The second common intermediate layer COM2 can include an electron transport layer ETL, a hole blocking layer HBL, and an electron injection layer EIL, among others; however, the embodiments of the present disclosure are not limited thereto.

For example, the common electrode CE can be electrically connected to a ground voltage line VSSL. A ground voltage VSS, which is one type of common voltage, can be applied to the common electrode CE through the ground voltage line VSSL. The pixel electrode PE can be electrically connected, either directly or indirectly (via another transistor), to a first node Na of the driving transistor DT in each sub-pixel SP.

Each light-emitting device ED can be formed in an overlapping portion of the pixel electrode PE, the intermediate emission layer EML in the light-emitting layer EL, and the common electrode CE. A predetermined emission area can be formed by each light-emitting device ED. For example, the emission area of each light-emitting device ED can include an overlapping region of the pixel electrode PE, the intermediate emission layer EML in the light-emitting layer EL, and the common electrode CE.

The driving transistor DT can be a transistor for supplying a driving current to the light-emitting device ED. The driving transistor DT can be connected between a driving voltage line VDDL and the light-emitting device ED.

The driving transistor DT can include a first node Na, a second node Nb, and a third node Nc. The first node Na can be electrically connected to the light-emitting device ED, the second node Nb can receive the data signal VDATA, and the third node Nc can receive a driving voltage VDD, which is another type of common voltage, from the driving voltage line VDDL. The driving transistor DT can be connected between the first node Na and the third node Nc.

Hereinafter, for convenience of explanation, a case will be described as an example in which, in the driving transistor DT, the second node Nb is a gate node, the first node Na is a source node, and the third node Nc is a drain node; however, the embodiments of the present disclosure are not limited thereto.

The scan transistor ST included in the sub-pixel circuit SPC illustrated in FIG. 2 can be a switching transistor for delivering the data signal VDATA, which is a video signal, to the gate node (second node Nb) of the driving transistor DT.

The scan transistor ST can be controlled to be turned on and off by a scan signal SC, which is one type of gate signal applied through a scan line SCL, which is one type of gate line GL, thereby controlling the electrical connection between the second node Nb of the driving transistor DT and the data line DL. A drain electrode or source electrode of the scan transistor ST can be electrically connected to the data line DL, a source electrode or drain electrode of the scan transistor ST can be electrically connected to the second node Nb of the driving transistor DT, and a gate electrode of the scan transistor ST can be electrically connected to the scan line SCL.

The storage capacitor Cst can be electrically connected between the first node Na and the second node Nb of the driving transistor DT. The storage capacitor Cst can include at least one capacitor electrode electrically connected to, or corresponding to, the first node Na of the driving transistor DT and at least one capacitor electrode electrically connected to, or corresponding to, the second node Nb of the driving transistor DT.

The display panel 110 can have a top emission structure or a bottom emission structure. When the display panel 110 has a top emission structure, at least a portion of the sub-pixel circuit SPC can vertically overlap at least a portion of the light-emitting device ED. Accordingly, the area of the emission region can be increased and the aperture ratio can be improved. When the display panel 110 has a bottom emission structure, the sub-pixel circuit SPC may not vertically overlap the light-emitting device ED.

The sub-pixel circuit SPC can have a 2T (Transistor) 1C (Capacitor) structure including two transistors DT and ST and one capacitor Cst. In some cases, it can further include one or more additional transistors or one or more additional capacitors.

The circuit elements in each sub-pixel SP (for example, the light-emitting device ED implemented as an organic light-emitting diode OLED including an organic material) are vulnerable to external moisture or oxygen. Accordingly, the encapsulation layer 200 can be disposed on the display panel 110. The encapsulation layer 200 can prevent or reduce external moisture or oxygen from penetrating into the circuit elements (for example, the light-emitting device ED). The encapsulation layer 200 can be configured in various forms so that the light-emitting devices ED do not come into contact with moisture or oxygen. For example, the encapsulation layer 200 can be composed of two or more layers in which an organic film and an inorganic film are alternately stacked; however, the embodiments of the present disclosure are not limited thereto.

The display device 100 according to embodiments of the present disclosure can include a touch sensor layer 210 on which a touch sensor is formed, and a touch sensing circuit for sensing the touch sensor formed on the touch sensor layer 210 to determine the presence or absence of a touch or a touch coordinate, in order to provide a touch sensing function. The touch sensor layer 210 can also be referred to as a touch unit or touch sensing unit.

For example, the touch sensing circuit can include a touch driving circuit 220 configured to drive and sense the touch sensor formed on the touch sensor layer 210 to generate and output touch sensing data, and a touch controller 230 configured to determine the presence or absence of a touch or a touch coordinate using the touch sensing data provided from the touch driving circuit 220.

When the touch sensor layer 210 is embedded in the display panel 110, the display panel 110 can further include a plurality of touch pads TP to which the touch driving circuit 220 is electrically connected, in addition to the plurality of touch electrodes corresponding to the touch sensor, and a plurality of touch routing lines TL for electrically connecting the plurality of touch electrodes to the plurality of touch pads TP.

The touch driving circuit 220 can supply a touch driving signal to at least one of the plurality of touch electrodes and sense at least one of the plurality of touch electrodes to generate touch sensing data.

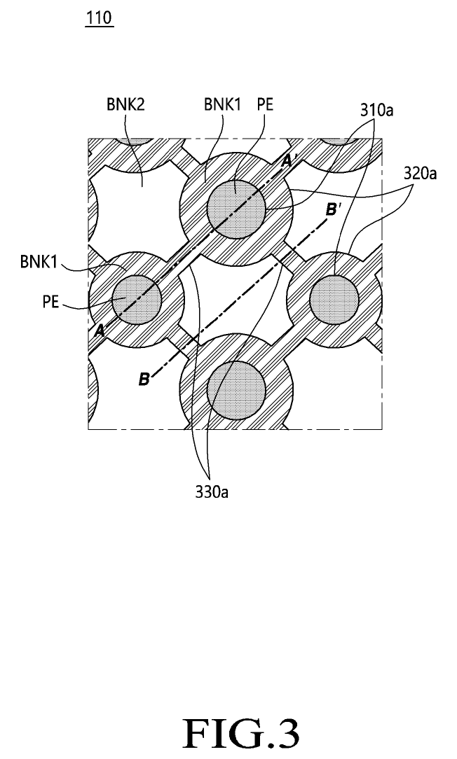

FIGS. 3 to 5 illustrate examples of the display panel 110 according to embodiments of the present disclosure. For example, FIG. 3 is a plan view of an area including a plurality of sub-pixels in the display panel 110 according to one embodiment of the present disclosure.

Referring to FIG. 3, the display panel 110 according to embodiments of the present disclosure can include the substrate 111, the pixel electrode PE, a first bank BNK1, and a second bank BNK2.

The pixel electrode PE can be formed for each sub-pixel on the substrate 111. The pixel electrode PE can include a metal electrode formed of one or more multilayers.

The first bank BNK1 can be disposed so as to surround the pixel electrode PE.

The first bank BNK1 can include an opaque organic material. Specifically, the first bank BNK1 can include an organic material mixed with a black material capable of absorbing light. For example, the black material can include black pigment, carbon black, or aniline black; however, the embodiments of the present disclosure are not limited thereto. Because the black material can block light from the outside or block light reflected from the outside, the luminance of the display device can be further improved.

The first bank BNK1 can serve to define the sub-pixel, for example, the emission portion. An area where the first bank BNK1 is not disposed and the pixel electrode PE is exposed can be an emission portion, and an area where the first bank BNK1 is disposed can be a non-emission portion.

The first bank BNK1 can include a plurality of first holes 310a overlapping the pixel electrode PE. An area where a portion of the upper surface of the pixel electrode PE is exposed by the first holes 310a of the first bank BNK1 can be the emission portion of the sub-pixel.

The second bank BNK2 can be disposed so as to surround the first bank BNK1.

In a plan view of the display panel 110, the second bank BNK2 can be disposed between the first bank BNK1 and another first bank BNK1 adjacent to the first bank BNK1.

The second bank BNK2 can include a transparent organic material. For example, the second bank BNK2 can include acryl resin, epoxy resin, phenolic resin, polyamide resin, or polyimide resin; however, the embodiments of the present disclosure are not limited thereto.

The second bank BNK2 can include a plurality of second holes 320a overlapping the plurality of first holes 310a. Through the second holes 320a of the second bank BNK2, a portion of the upper surface of the pixel electrode PE and a portion of the upper surface of the first bank BNK1 can be exposed.

The second bank BNK2 can include fine regions 330a that do not overlap the plurality of first holes 310a.

The fine region 330a can be disposed between the plurality of second holes 320a. The fine region 330a can be disposed between one of the second holes 320a and another second hole 320a that is located closest to the one second hole 320a. For example, the fine region 330a can be disposed between one of the second holes 320a and each of four other second holes 320a adjacent thereto.

The fine regions 330a and the plurality of second holes 320a can be integrally connected, but are not limited thereto. The integrally connected fine regions 330a and the plurality of second holes 320a can have a mesh structure.

The size of the fine regions 330a can be equal to or smaller than the size of the plurality of first holes 310a and the size of the plurality of second holes 320a.

The plurality of first holes 310a and the plurality of second holes 320a can have a circular structure, but are not limited thereto. The diameter of the second holes 320a can be greater than or equal to the diameter of the first holes 310a.

The width of the fine regions 330a can be equal to or smaller than the diameters of the plurality of first holes 310a and the plurality of second holes 320a having a circular structure.

By disposing the fine regions 330a in the second bank BNK2, the spreadability of an organic encapsulation layer disposed on the first bank BNK1 can be improved by a capillary effect. As a result, the organic encapsulation layer can be interposed in the plurality of first holes 310a and the plurality of second holes 320a and uniformly disposed over the entire display panel 110.

Line A-A’ in FIG. 3 is a cutting line passing through the centers of two adjacent sub-pixels. For example, A-A’ is a cutting line passing through the first bank BNK1, the pixel electrode PE, and the fine regions 330a.

Referring to FIG. 3, line B-B’ is a cutting line passing through an area in which no pixel electrode PE of the sub-pixel is disposed and in which the fine regions 330a are disposed on the second bank BNK2.

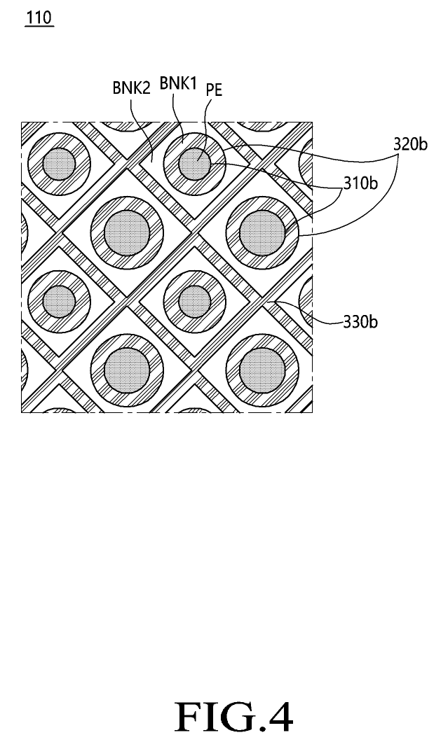

FIG. 4 is a plan view of an area including a plurality of sub-pixels in the display panel 110 according to another embodiment of the present disclosure.

Referring to FIG. 4, the display panel 110 according to embodiments of the present disclosure can include the substrate 111, the pixel electrode PE, the first bank BNK1, the second bank BNK2, a plurality of first holes 310b, a plurality of second holes 320b, and the fine regions 330b, and the overlapping description with the configuration of FIG. 3 can be omitted or may be briefly provided.

The second bank BNK2 can include fine regions 330b that do not overlap the plurality of first holes 310b.

The fine regions 330b can be disposed between the plurality of second holes 320b. The fine regions 330b can be disposed between one of the plurality of second holes 320b and another second hole 320b adjacent to the one second hole 320b.

The fine regions 330b and the plurality of second holes 320b can be spaced apart from each other. The fine regions 330b can be disposed so as not to be in contact with and not to be integrally connected to the plurality of second holes 320b.

The fine regions 330b can surround the outer peripheries of the plurality of second holes 320b. For example, the fine regions 330b can have a lattice grid structure, and the sub-pixel area can be defined by the lattice grid structure.

The size of the fine regions 330b can be different from the size of the plurality of first holes 310b and the size of the plurality of second holes 320b.

The plurality of first holes 310b and the plurality of second holes 320b can have a circular structure, but are not limited thereto. The width of the fine regions 330b can be equal to or smaller than the diameters of the plurality of first holes 310b and the plurality of second holes 320b having a circular structure.

By disposing the fine regions 330b in the second bank BNK2, the spreadability of an organic encapsulation layer disposed on the first bank BNK1 can be improved by a capillary effect. As a result, the organic encapsulation layer can be interposed in the plurality of first holes 310b and the plurality of second holes 320b and uniformly disposed over the entire display panel 110.

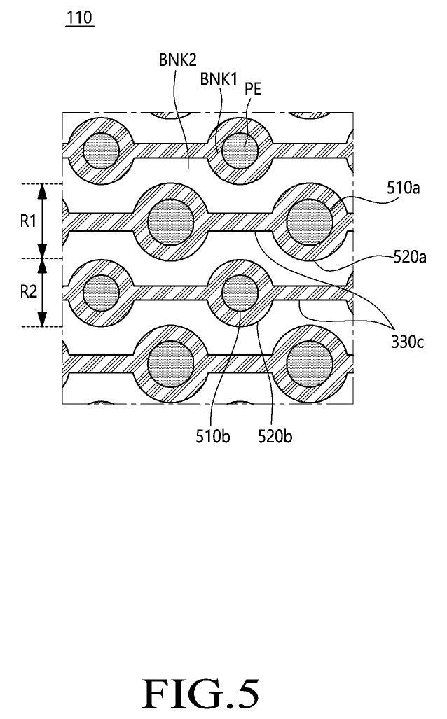

FIG. 5 is a plan view of an area including a plurality of sub-pixels in the display panel 110 according to still another embodiment of the present disclosure.

Referring to FIG. 5, the display panel 110 according to embodiments of the present disclosure can include the substrate 111, the pixel electrode PE, the first bank BNK1, the second bank BNK2, a plurality of first holes 510a and 510b, a plurality of second holes 520a and 520b, and fine regions 330c, and the overlapping description with the configuration of FIG. 3 can be omitted or may be briefly provided.

The plurality of first holes 510a and 510b and the plurality of second holes 520a and 520b can be arranged in a plurality of rows. The plurality of rows can include a first row R1 and a second row R2 adjacent to each other.

The plurality of second holes 520a and 520b can include a plurality of third holes 520a arranged in the first row R1 and a plurality of fourth holes 520b arranged in the second row R2.

For example, the sizes of the third holes 520a and the fourth holes 520b can be different. When the third holes 520a and the fourth holes 520b have a circular structure, the diameter of the third holes 520a can be greater than or equal to the diameter of the fourth holes 520b.

In another example, the sizes of the third holes 520a and the fourth holes 520b can be the same.

The second bank BNK2 can include the fine regions 330c that do not overlap the plurality of first holes 510a and 510b.

The fine regions 330c can be disposed between the plurality of third holes 520a, and the plurality of third holes 520a and the fine regions 330c can be integrally connected in the first row R1.

The fine regions 330c can be disposed between the plurality of fourth holes 520b, and the plurality of fourth holes 520b and the fine regions 330c can be integrally connected in the second row R2.

The size of the fine regions 330c can be different from the sizes of the plurality of first holes 510a and 510b and the plurality of second holes 520a and 520b.

The plurality of first holes 510a and 510b and the plurality of second holes 520a and 520b can have a circular structure, but are not limited thereto. The width of the fine regions 330c can be equal to or smaller than the diameters of the plurality of first holes 510a and 510b and the plurality of second holes 520a and 520b having a circular structure.

By disposing the fine regions 330c in the second bank BNK2, the spreadability of an organic encapsulation layer disposed on the first bank BNK1 can be improved by a capillary effect. As a result, the organic encapsulation layer can be interposed in the plurality of first holes 510a and 510b and the plurality of second holes 520a and 520b and uniformly disposed over the entire display panel 110.

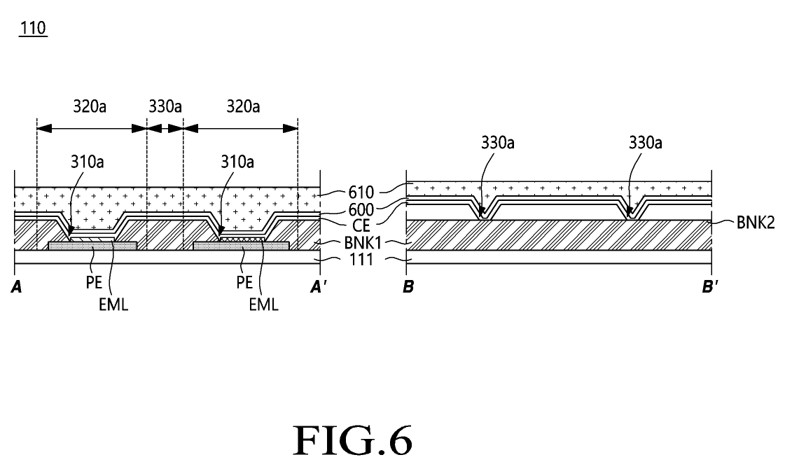

FIG. 6 is a cross-sectional view of the display panel 110 according to embodiments of the present disclosure, taken along lines A-A’ and B-B’ of FIG. 3. For example, FIG. 6 illustrates the display panel 110 with some configurations omitted for convenience of explanation, and the display panel 110 according to embodiments of the present disclosure can include additional configurations other than those disclosed in FIG. 6.

Referring to FIG. 6, the display panel 110 according to embodiments of the present disclosure can include the substrate 111, the pixel electrode PE disposed on the substrate 111, the first bank BNK1 disposed on the pixel electrode PE, the plurality of first holes 310a, the plurality of second holes 320a, and the fine regions 330a, and the overlapping description with the configuration of FIG. 5 can be omitted or may be briefly provided.

Referring to a region showing line A-A’ of FIG. 6, the first bank BNK1 can include the plurality of first holes 310a overlapping the pixel electrode PE. For example, the top surface of the pixel electrode PE can be exposed through the plurality of first holes 310a formed in the first bank BNK1.

The second bank BNK2 can be formed on the first bank BNK1 so as to overlap a part of the top surface of the first bank BNK1. In this case, the first bank BNK1 disclosed in FIG. 3 can be the top surface of the first bank BNK1 not overlapped with the second bank BNK2.

Line A-A’ of FIG. 6 can be a cutting line passing through the plurality of second holes 320a and the fine regions 330a disposed therebetween. Accordingly, although the second bank BNK2 is not illustrated in A-A’ of FIG. 6, the first bank BNK1 and the second bank BNK2 can be disposed to form a step in the sub-pixel area.

The second bank BNK2 can include the plurality of second holes 320a so as to overlap the plurality of holes formed in the first bank BNK1, and can be disposed on the first bank BNK1. For example, the top surface of the pixel electrode PE can be exposed through the plurality of second holes 320a formed in the second bank BNK2.

A light-emitting layer EL can be disposed on the pixel electrode PE.

Referring to the region showing line A-A’ of FIG. 6, the common electrode CE can be disposed on the first bank BNK1 and the light-emitting layer EL.

Referring to a region showing line B-B’ of FIG. 6, the common electrode CE can be disposed on the second bank BNK2.

Referring to FIG. 6, a first inorganic encapsulation layer 800 can be disposed on the pixel electrode PE.

Accordingly, the common electrode CE and the first inorganic encapsulation layer 800 can be formed along the step of the first bank BNK1 and the second bank BNK2.

Referring to the region showing line A-A’ of FIG. 6, an organic encapsulation layer 610 can be disposed on the first inorganic encapsulation layer 800.

The organic encapsulation layer 610 can prevent or reduce moisture or oxygen from penetrating into the light-emitting device, for example, the light-emitting layer EL, in the display panel 110.

The organic encapsulation layer 610 can include an organic material having flowability.

To form the organic encapsulation layer 610 on the first inorganic encapsulation layer 800, the organic material can be applied onto the second bank BNK2. The organic material having flowability, for example, a property of liquid flow (hereinafter referred to as the “first property”), can spread across the entire substrate 111 due to the step formed by the first bank BNK1 and the second bank BNK2.

Accordingly, the organic material can flow down along the step formed by the first bank BNK1 and the second bank BNK2 to fill the plurality of holes 310a and 320a included in the first bank BNK1 and the second bank BNK2.

Referring to the region showing line A-A’ of FIG. 6, the organic encapsulation layer 610 can be interposed in the plurality of first holes 310a and the plurality of second holes 320a.

When the thickness of the organic encapsulation layer 610 is large, for example, when the amount of organic material is sufficiently large, the organic encapsulation layer 610 can be relatively easily interposed in the plurality of holes included in the first bank BNK1 and the second bank BNK2.

In contrast, when the thickness of the organic encapsulation layer 610 is small, for example, when the amount of organic material is insufficient, the organic encapsulation layer 610 may not be interposed in the plurality of first holes 310a and the plurality of second holes 320a, and can stop on the second bank BNK2. In this case, one end and the other end of the organic encapsulation layer 610 can be in contact with one end and the other end of the top surface of the second bank BNK2, respectively.

The arrangement of the organic encapsulation layer 610 described above can result from another property of the organic material (hereinafter referred to as the “second property”). For example, the more inclined the taper angle of the second bank BNK2, the less the organic material can spread.

Accordingly, in the display panel 110, a coating defect of the organic encapsulation layer 610 can occur, which can deteriorate the light-emitting device.

The non-spreading phenomenon of the organic encapsulation layer 610 caused by the second property of the organic material can be improved by disposing the fine regions 330a.

Referring to FIG. 6, the organic encapsulation layer 610 can be interposed in the fine regions 330a included in the second bank BNK2.

By being interposed in the fine regions 330a, the spreadability of the organic material can be improved by a capillary effect. As a result, even if the thickness of the organic encapsulation layer 610 is reduced, it can overcome the second property of the organic material and flow down along the step of the second bank BNK2 and the first bank BNK1.

Consequently, the organic encapsulation layer 610 can be interposed in the plurality of first holes 310a, the plurality of second holes 320a, and the fine regions 330a.

For example, in the embodiments according to FIGS. 3 to 5, even when the thickness of the organic encapsulation layer 610 is reduced, by including the fine regions 330a on the second bank BNK2, the organic encapsulation layer 610 is structured to be uniformly disposed over the entire display panel 110.

The height of the organic encapsulation layer 610 in the region where the plurality of first holes 310a and the plurality of second holes 320a overlap can be equal to or less than the height of the organic encapsulation layer 610 in the region where the fine regions 330a are located.

The thickness of the organic encapsulation layer 610 interposed in the plurality of first holes 310a and the plurality of second holes 320a can be equal to or greater than the thickness of the organic encapsulation layer 610 interposed in the fine regions 330a.

The size of the fine regions 330a can be equal to or less than the sizes of the plurality of first holes 310a and the plurality of second holes 320a. Accordingly, the thickness of the organic encapsulation layer 610 interposed in the fine regions 330a can also be smaller than the thickness of the organic encapsulation layer 610 interposed in the plurality of first holes 310a and the plurality of second holes 320a.

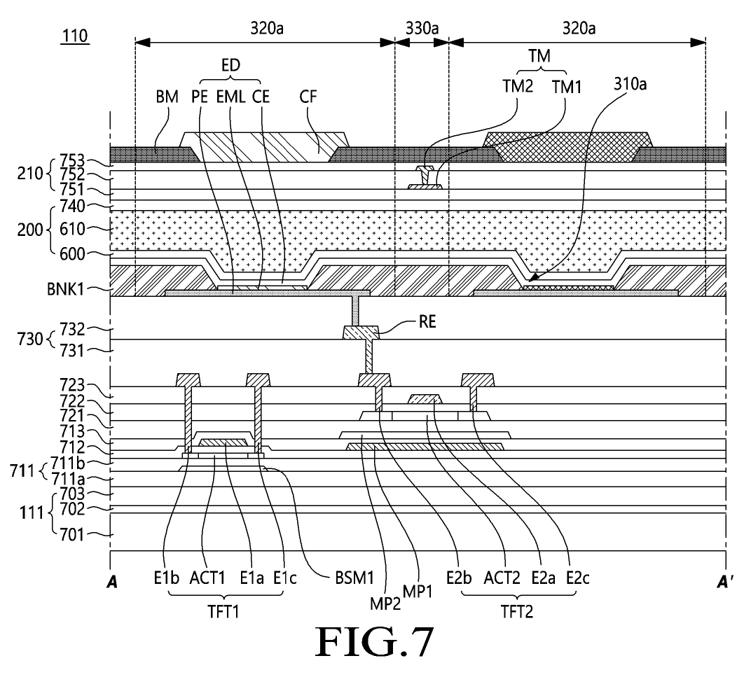

FIG. 7 is a cross-sectional view of the display panel 110 according to embodiments of the present disclosure, taken along line A-A’ of FIG. 5. For example, FIG. 7 can include all or some of the components omitted from the display panel 110 of FIG. 6.

Referring to FIG. 7, the display panel 110 according to embodiments of the present disclosure can include the substrate 111, a transistor portion, a light-emitting device portion, and an encapsulation portion, but embodiments of the present disclosure are not limited thereto.

The substrate 111 can be a single layer or a multilayer. In the case where the substrate 111 is a multilayer, the substrate 111 can include a first substrate 701, an intermediate substrate layer 702, and a second substrate 703. The intermediate substrate layer 702 can be positioned between the first substrate 701 and the second substrate 703. For example, each of the first substrate 701 and the second substrate 703 can be a polyimide (PI) layer, but embodiments of the present disclosure are not limited thereto. The intermediate substrate layer 702 can be an inorganic insulating layer, but embodiments of the present disclosure are not limited thereto. The intermediate substrate layer 702 can block charges, when charges are accumulated in the first substrate 701, which is a polyimide layer, from affecting transistors disposed on the second substrate 703, which is also a polyimide layer.

In addition, the intermediate substrate layer 702 can block moisture components from penetrating upward through the first substrate 701. For example, the intermediate substrate layer 702 can be formed of a single layer of silicon nitride (SiNx) or silicon oxide (SiOx), or a multilayer thereof, and can be formed as a double layer of silicon dioxide (SiO₂) and silicon nitride (SiNx), but is not limited thereto.

The transistor portion can include insulating layers 711, 712, 713, 721, 722, and 723 on the substrate 111, thin-film transistors TFT1 and TFT2, a storage capacitor, and various electrodes and signal lines.

The thin-film transistors included in the transistor portion can include a first thin-film transistor TFT1 and a second thin-film transistor TFT2.

The first thin-film transistor TFT1 can include a first active layer ACT1, a first electrode E1a, a second electrode E1b, and a third electrode E1c.

The first electrode E1a is a gate electrode, the second electrode E1b can be a source electrode or a drain electrode, and the third electrode E1c can be a drain electrode or a source electrode. Hereinafter, for convenience of description, the first electrode E1a is referred to as a first gate electrode E1a, the second electrode E1b can be referred to as a first source electrode E1b, and the third electrode E1c is referred to as a first drain electrode E1c. However, embodiments of the present disclosure are not limited thereto.

The first active layer ACT1 can include a first semiconductor material. For example, the first semiconductor material can include an oxide semiconductor, amorphous silicon, polysilicon, or low-temperature polysilicon (LTPS), but embodiments of the present disclosure are not limited thereto. The first thin-film transistor TFT1 can be implemented as a p-channel transistor or an n-channel transistor, but embodiments of the present disclosure are not limited thereto.

The second thin-film transistor TFT2 can include a second active layer ACT2, a fourth electrode E2a, a fifth electrode E2b, and a sixth electrode E2c.

The fourth electrode E2a is a gate electrode, the fifth electrode E2b can be a source electrode or a drain electrode, and the sixth electrode E2c can be a drain electrode or a source electrode. Hereinafter, for convenience of description, the fourth electrode E2a is referred to as a second gate electrode E2a, the fifth electrode E2b can be referred to as a second source electrode E2b, and the sixth electrode E2c is referred to as a second drain electrode E2c. However, embodiments of the present disclosure are not limited thereto.

The second active layer ACT2 can include a second semiconductor material. For example, the second semiconductor material can include an oxide semiconductor, amorphous silicon, polysilicon, or low-temperature polysilicon (LTPS), but embodiments of the present disclosure are not limited thereto. The second thin-film transistor TFT2 can be implemented as a p-channel transistor or an n-channel transistor, but embodiments of the present disclosure are not limited thereto.

The types of semiconductor materials of the first active layer ACT1 of the first thin-film transistor TFT1 and the second active layer ACT2 of the second thin-film transistor TFT2 can be as follows.

In one example, the first active layer ACT1 of the first thin-film transistor TFT1 and the second active layer ACT2 of the second thin-film transistor TFT2 can include oxide semiconductor materials. In another example, the first active layer ACT1 of the first thin-film transistor TFT1 and the second active layer ACT2 of the second thin-film transistor TFT2 can include low-temperature polysilicon semiconductor materials. In another example, the first active layer ACT1 of the first thin-film transistor TFT1 can include a low-temperature polysilicon semiconductor material, and the second active layer ACT2 of the second thin-film transistor TFT2 can include an oxide semiconductor material. In another example, the first active layer ACT1 of the first thin-film transistor TFT1 can include an oxide semiconductor material, and the second active layer ACT2 of the second thin-film transistor TFT2 can include a low-temperature polysilicon semiconductor material.

The purposes of the transistors in the display area DA can be as follows.

In one example, all of the transistors in each sub-pixel SP can be implemented as the first thin-film transistor TFT1. In another example, all of the transistors in each sub-pixel SP can be implemented as the second thin-film transistor TFT2. In another example, some of the transistors in each sub-pixel SP can be implemented as the first thin-film transistor TFT1, and the remaining transistors can be implemented as the second thin-film transistor TFT2. For example, each sub-pixel SP can include at least one first thin-film transistor TFT1 and at least one second thin-film transistor TFT2.

In the case where, in each sub-pixel SP, some of the transistors are implemented as the first thin-film transistor TFT1 and the remaining transistors are implemented as the second thin-film transistor TFT2, the following examples can be possible.

In one example, in each sub-pixel SP, a driving transistor DT can be implemented as the first thin-film transistor TFT1, and transistors other than the driving transistor DT (for example, a scan transistor ST, a light emission control transistor, etc.) can be implemented as the second thin-film transistor TFT2.

In another example, in each sub-pixel SP, the driving transistor DT can be implemented as the second thin-film transistor TFT2, and transistors other than the driving transistor DT (for example, a scan transistor ST, a light emission control transistor, etc.) can be implemented as the first thin-film transistor TFT1.

The second thin-film transistor TFT2 connected to the pixel electrode PE of the light-emitting device ED can be the driving transistor DT or another transistor depending on the configuration of the sub-pixel circuit. For example, in FIG. 7, the second thin-film transistor TFT2 connected to the pixel electrode PE of the light-emitting device ED can be a light emission control transistor connected between the driving transistor DT and the light-emitting device ED.

The second active layer ACT2 of the second thin film transistor TFT2 can be positioned higher from the substrate 111 than the first active layer ACT1 of the first thin film transistor TFT1.

A first buffer layer 711 can be disposed below the first active layer ACT1 of the first thin film transistor TFT1, and a second buffer layer 721 can be disposed below the second active layer ACT2 of the second thin film transistor TFT2. For example, the first active layer ACT1 of the first thin film transistor TFT1 can be positioned on the first buffer layer 711, and the second active layer ACT2 of the second thin film transistor TFT2 can be positioned on the second buffer layer 721. The second buffer layer 721 can be positioned higher than the first buffer layer 711.

The storage capacitor can be disposed in various metal layers in the display panel 110. For example, the storage capacitor can include a first capacitor electrode MP1 and a second capacitor electrode MP2.

The light emitting device portion can include a plurality of light emitting devices ED disposed on the planarization layer 730. Each of the plurality of light emitting devices ED can include the pixel electrode PE, the light-emitting layer EL, and the common electrode CE.

The encapsulation portion can include the encapsulation layer 200 on the plurality of light emitting devices ED. The encapsulation layer 200 can be a single layer or a multilayer, but embodiments of the present disclosure are not limited thereto.

Hereinafter, with reference to FIG. 7, the structure or vertical structure of the display panel 110 according to embodiments of the present disclosure will be described in more detail.

Referring to FIG. 7, the first buffer layer 711 can be disposed on the substrate 111. The first buffer layer 711 can be a single layer or a multilayer, but embodiments of the present disclosure are not limited thereto. When the first buffer layer 711 is a multilayer, it can include a lower buffer layer 711a and an upper buffer layer 711b.

The first active layer ACT1 of the first thin film transistor TFT1 can be disposed on the first buffer layer 711. The first active layer ACT1 can include a channel region in which a channel is formed, a source connection region on one side of the channel region, and a drain connection region on the other side of the channel region.

A first gate insulating layer 712 can be disposed on the first active layer ACT1 of the first thin film transistor TFT1. A first gate electrode E1a of the first thin film transistor TFT1 can be disposed on the first gate insulating layer 712. A first interlayer insulating layer 713 can be disposed on the first gate electrode E1a of the first thin film transistor TFT1. The metal layer in which the first gate electrode E1a of the first thin film transistor TFT1 is disposed can be referred to as a first gate metal layer.

The second buffer layer 721 can be disposed on the first interlayer insulating layer 713.

The second active layer ACT2 of the second thin film transistor TFT2 can be disposed on the second buffer layer 721. The second active layer ACT2 can include a channel region in which a channel is formed, a source connection region on one side of the channel region, and a drain connection region on the other side of the channel region.

A second gate insulating layer 722 can be disposed on the second active layer ACT2 of the second thin film transistor TFT2. The second gate electrode E2a of the second thin film transistor TFT2 can be disposed thereon. A second interlayer insulating layer 723 can be disposed on the second gate electrode E2a of the second thin film transistor TFT2. The second gate electrode E2a of the second thin film transistor TFT2 can be referred to as a second gate metal layer.

The first source electrode E1b and the first drain electrode E1c of the first thin film transistor TFT1, and the second source electrode E2b and the second drain electrode E2c of the second thin film transistor TFT2 can be disposed on the second interlayer insulating layer 723.

The first source electrode E1b and the first drain electrode E1c of the first thin film transistor TFT1 can be connected to the source connection region and the drain connection region of the first active layer ACT1 through holes in the second interlayer insulating layer 723, the second gate insulating layer 722, the second buffer layer 721, the first interlayer insulating layer 713, and the first gate insulating layer 712.

The second source electrode E2b and the second drain electrode E2c of the second thin film transistor TFT2 can be connected to the source connection region and the drain connection region of the second active layer ACT2 through holes in the second interlayer insulating layer 723 and the second gate insulating layer 722.

For example, the storage capacitor can be formed by the first capacitor electrode MP1 and the second capacitor electrode MP2. In some cases, the storage capacitor can be formed by three or more capacitor electrodes, and can have a form in which two or more capacitors are connected in parallel.

The first capacitor electrode MP1 can include the same first gate metal as the first gate electrode E1a of the first thin film transistor TFT1 on the first gate insulating layer 712, and can be disposed in the first gate metal layer, but embodiments of the present disclosure are not limited thereto. For example, the second capacitor electrode MP2 can be disposed on the first interlayer insulating layer 713.

The transistor portion can further include a first shield pattern BSM1 disposed on the substrate 111. The first shield pattern BSM1 can overlap the first active layer ACT1 of the first thin film transistor TFT1. The first shield pattern BSM1 can be disposed below the first active layer ACT1 of the first thin film transistor TFT1. For example, the first shield pattern BSM1 can be disposed between the substrate 111 and the first buffer layer 711, or between the lower buffer layer 711a and the upper buffer layer 711b.

The planarization layer 730 can be disposed on the first thin film transistor TFT1 and the second thin film transistor TFT2, and can be disposed below the light-emitting device ED. The planarization layer 730 can be an organic insulating layer including an organic insulating material.

For example, the planarization layer 730 can be configured of at least one layer. In another example, the planarization layer 730 can include two layers. The example in FIG. 7 is a case in which the planarization layer 730 includes a first planarization layer 731 and a second planarization layer 732. In another example, the planarization layer 730 can include three or more layers. Embodiments of the present disclosure are not limited thereto.

The first planarization layer 731 can be disposed on first source electrode E1b and first drain electrode E1c of first thin film transistor TFT1, and on second source electrode E2b and second drain electrode E2c of second thin film transistor TFT2. For example, the first planarization layer 731 can be disposed on both the first thin film transistor TFT1 and the second thin film transistor TFT2. For example, the first planarization layer 731 can be disposed so as to cover both the first thin film transistor TFT1 and the second thin film transistor TFT2.

A connection electrode RE can be disposed on the first planarization layer 731. In one example, the connection electrode RE (or pixel electrode PE) can be electrically connected to a source electrode or a drain electrode of the first thin film transistor TFT1. The connection electrode RE can electrically connect the first source electrode E1b of the first thin film transistor TFT1 to the pixel electrode PE.

In another example, the connection electrode RE (or pixel electrode PE) can be electrically connected to a source electrode or a drain electrode of the second thin film transistor TFT2. The connection electrode RE can electrically connect the second source electrode E2b of the second thin film transistor TFT2 to the pixel electrode PE.

The connection electrode RE can be disposed in a second source-drain metal layer on the first planarization layer 731, and can include a second source-drain metal.

The second planarization layer 732 can be disposed on the connection electrode RE.

A light-emitting device unit can be disposed on the second planarization layer 732. The light-emitting device ED can be formed on the second planarization layer 732. The light-emitting device ED can include the pixel electrode PE, the light-emitting layer EL, and the common electrode CE. A light-emitting region of the light-emitting device ED can be formed in an area where the pixel electrode PE, the light-emitting layer EL, and the common electrode CE overlap and contact each other.

The pixel electrode PE can be disposed on the second planarization layer 732. The pixel electrode PE can be electrically connected to the connection electrode RE through a hole in the second planarization layer 732.

The first bank BNK1 disposed on the pixel electrode PE can include the plurality of first holes 310a. The first holes 310a can expose a portion of the pixel electrode PE to form a light-emitting region. The first holes 310a can overlap a portion of the pixel electrode PE.

The light-emitting layer EL of the light-emitting device ED can be disposed on the pixel electrode PE; however, it is not limited thereto. For example, the light-emitting layer EL can be disposed on a portion of the pixel electrode PE and on the first bank BNK1.

The common electrode CE can be disposed on the light-emitting layer EL. The common electrode CE can be disposed to cover the light-emitting layer EL, side surfaces of the first bank BNK1, and an upper surface of the first bank BNK1.

The encapsulation layer 200 can be formed on the common electrode CE.

The encapsulation layer 200 can prevent or reduce moisture or oxygen from penetrating into the light-emitting device ED. For example, the encapsulation layer 200 can prevent or reduce moisture or oxygen from penetrating into the organic material included in the light-emitting layer EL of the light-emitting device ED. The encapsulation layer 200 can be composed of a single layer or multiple layers; however, embodiments of the present disclosure are not limited thereto.

In one example, the encapsulation layer 200 can include a first inorganic encapsulation layer 600, the organic encapsulation layer 610, and a second inorganic encapsulation layer 743; however, embodiments of the present disclosure are not limited thereto.

The display panel 110 according to embodiments of the present disclosure can also have a built-in touch sensor. In this case, the display panel 110 according to embodiments of the present disclosure can include the touch sensor layer 210 formed on the encapsulation layer 200 and in which the touch sensor is formed.

The touch sensor layer 210 can include a plurality of touch electrodes corresponding to the touch sensor. For example, to form the plurality of touch electrodes, the touch sensor layer 210 can include a first touch metal layer in which a plurality of first touch metals TM1 are disposed, and a second touch metal layer in which a plurality of second touch metals TM2 are disposed. In this case, the touch sensor layer 210 can further include a touch interlayer insulating layer 752 disposed between the first touch metal layer and the second touch metal layer.

For example, one of the first touch metal layer and the second touch metal layer can be a sensor metal layer and the other can be a bridge metal layer.

In another example, each of the first touch metal layer and the second touch metal layer can be both a sensor metal layer and a bridge metal layer. For example, the first touch metal layer can be both a sensor metal layer and a bridge metal layer, and the second touch metal layer can be both a sensor metal layer and a bridge metal layer. In this case, the plurality of first touch metals TM1 disposed in the first touch metal layer can include sensor metals and bridge metals, and the plurality of second touch metals TM2 disposed in the second touch metal layer can include sensor metals and bridge metals.

The touch sensor layer 210 can further include a touch buffer layer 751 disposed on the encapsulation layer 200. The touch buffer layer 751 can be disposed between the encapsulation layer 200 and the touch metal layers. For example, the first touch metal layer can be disposed on the touch buffer layer 751, and the touch interlayer insulating layer 752 can be disposed on the first touch metal layer.

The touch sensor layer 210 can further include a touch protection layer 753 disposed to cover the touch metal layers. For example, the touch protection layer 753 can be disposed on the second touch metal layer.

For example, the touch buffer layer 751 can be an inorganic layer including an inorganic insulating material or an organic layer including an organic insulating material, the touch interlayer insulating layer 752 can be an inorganic layer including an inorganic insulating material or an organic layer including an organic insulating material, and the touch protection layer 753 can be an inorganic layer including an inorganic insulating material or an organic layer including an organic insulating material.

The plurality of first touch metals TM1 and the plurality of second touch metals TM2 can be arranged so as not to overlap with the light-emitting device ED. The plurality of first touch metals TM1 and the plurality of second touch metals TM2 can overlap with the first bank BNK1. Accordingly, the luminous efficiency of the light-emitting device ED can be improved.

The display panel 110 according to embodiments of the present disclosure can include a color filter CF disposed on the touch sensor layer 210.

The color filter CF can overlap with the light-emitting layer EL. The color filter CF can overlap with the plurality of first holes 310a and the plurality of second holes 320a.

Light emitted through the light-emitting device ED (hereinafter referred to as “emitted light”) can pass through the encapsulation layer 200 and the touch sensor layer 210 to reach the color filter CF.

The emitted light can travel in at least one direction in a straight line. For example, the emitted light can travel in a straight line in a direction (hereinafter, “the vertical direction”) from the light-emitting device ED toward the direction in which the encapsulation layer 200 and the color filter CF are stacked, or can travel in a direction at an angle different from the vertical direction.

Accordingly, if the distance from the light-emitting device ED to the color filter CF increases, the emitted light traveling in a direction other than the vertical direction may not be easily visible outside the display panel. For example, the viewing angle characteristics of the display device can deteriorate, and thus there is a need for a method to improve them.

The display panel according to embodiments of the present disclosure can reduce the thickness of the organic encapsulation layer 610 to minimize or reduce the path of light emitted from the light-emitting device ED until it exits the display panel. As a result, the thickness of the display panel can also be reduced.

The second characteristic of the organic material, namely, a non-spreading phenomenon occurring when the thickness of the organic encapsulation layer 610 is reduced, can be overcome through the fine region 330a disposed on the second bank BNK2.

As the organic encapsulation layer 610 is interposed in the fine region 330a, the organic encapsulation layer 610 disposed on the first bank BNK1 can have improved spreadability due to the capillary effect. As a result, the organic encapsulation layer 610 can be interposed in the plurality of first holes 310a and the plurality of second holes 320a and can be evenly disposed over the entire display panel.

Accordingly, it is possible to secure the reliability of the encapsulation layer while improving the deterioration of the viewing angle characteristics of the display panel according to embodiments of the present disclosure.

The display panel according to embodiments of the present disclosure can include a black matrix BM disposed on the touch sensor layer 210. The black matrix BM can be adjacent to the color filter CF and can be disposed between the plurality of color filters CF that are adjacent to each other.

The black matrix BM can overlap with the fine region 330a.

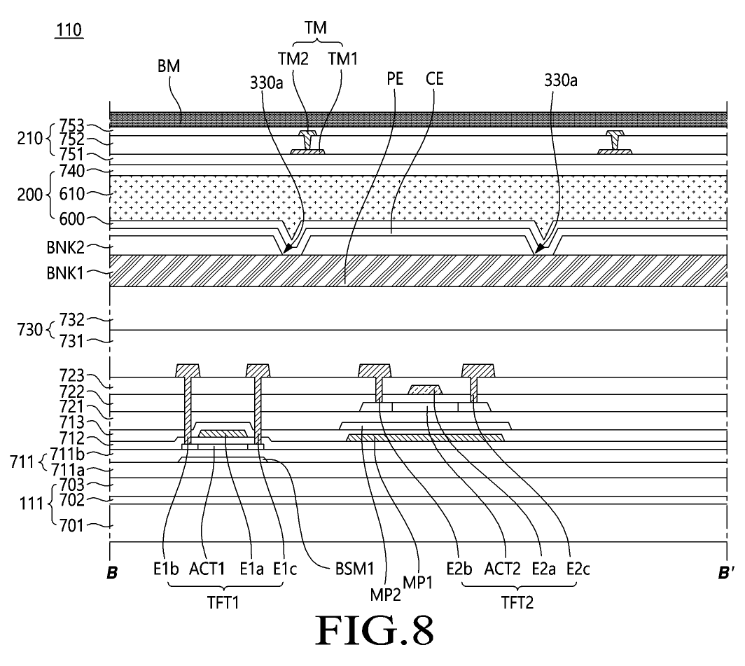

FIG. 8 is a cross-sectional view taken along line B-B’ of FIG. 5 of the display panel according to embodiments of the present disclosure. For example, FIG. 8 can include all or some of the configurations omitted from the display panel of FIG. 6.

Referring to FIG. 8, the display panel 110 according to embodiments of the present disclosure can include the substrate 111, a transistor unit, a light-emitting device unit, an encapsulation portion, and the touch sensor layer 210, but the embodiments of the present disclosure are not limited thereto. Descriptions overlapping with those of FIG. 7 can be omitted or may be briefly provided.

A fine region 330a can be disposed on the second bank BNK2.

The common electrode CE can be disposed on the second bank BNK2. As a result, the common electrode CE can cover the second bank BNK2 and the fine region 330a. For example, the common electrode CE can be in contact with the upper and side surfaces of the second bank BNK2, and can be in contact with a portion of the upper surface of the first bank BNK1 exposed by the second hole 320a of the second bank BNK2 and a portion of the upper surface of the first bank BNK1 exposed at the fine region 330a.

The first inorganic encapsulation layer 600 can be disposed on the common electrode CE, and the organic encapsulation layer 610 can be disposed on the first inorganic encapsulation layer 600.

Due to the common electrode CE and the inorganic encapsulation layer 600 overlapping with the plurality of second holes 320a, the width and thickness of the organic encapsulation layer 610 interposed in the fine region 330a can be reduced.

Accordingly, the spreadability of the organic encapsulation layer 610 can be improved by using the capillary effect in which the organic encapsulation layer 610 is interposed along the fine region 330a.

The display device according to embodiments of the present disclosure can be described as follows.

The display device according to embodiments of the present disclosure can include a substrate, a pixel electrode disposed on the substrate, a first bank disposed on the pixel electrode, a second bank disposed on the first bank, an encapsulation layer disposed on the second bank, and a color filter disposed on the encapsulation layer, wherein the first bank can include a plurality of first holes overlapping the pixel electrode, and the second bank can include a plurality of second holes overlapping the plurality of first holes, and fine regions not overlapping the plurality of first holes.

According to the display device of embodiments of the present disclosure, the encapsulation layer can include a first inorganic encapsulation layer disposed on the first bank and the second bank, an organic encapsulation layer disposed on the first inorganic encapsulation layer, and a second inorganic encapsulation layer disposed on the organic encapsulation layer, and the organic encapsulation layer can be interposed in the plurality of first holes, the plurality of second holes, and the fine regions.

According to the display device of embodiments of the present disclosure, the thickness of the organic encapsulation layer interposed in the plurality of first holes and the plurality of second holes can be equal to or greater than the thickness of the organic encapsulation layer interposed in the fine regions.

According to the display device of embodiments of the present disclosure, the height of the organic encapsulation layer in a region where the plurality of first holes and the plurality of second holes overlap can be lower than the height of the organic encapsulation layer in a region where the fine regions are located.

According to the display device of embodiments of the present disclosure, the fine regions can be disposed between the plurality of second holes, and the fine regions and the plurality of second holes can be integrally connected.

According to the display device of embodiments of the present disclosure, the integrally connected fine regions and the plurality of second holes can have a mesh shape.

According to the display device of embodiments of the present disclosure, the fine regions can be disposed between the plurality of second holes, and the fine regions and the plurality of second holes can be spaced apart from each other.

According to the display device of embodiments of the present disclosure, the fine regions can surround the outer peripheries of the plurality of second holes.

According to the display device of embodiments of the present disclosure, the fine regions can have a lattice grid shape.

According to the display device of embodiments of the present disclosure, the plurality of second holes can be arranged in a plurality of rows, the plurality of rows can include a first row and a second row that are adjacent to each other, and the plurality of second holes can include a plurality of third holes arranged in the first row and a plurality of fourth holes arranged in the second row.

According to the display device of embodiments of the present disclosure, the size of the third holes and the size of the fourth holes can be different.

According to the display device of embodiments of the present disclosure, the size of the third holes and the size of the fourth holes can be the same.

According to the display device of embodiments of the present disclosure, the plurality of third holes can be integrally connected with the fine regions disposed between the plurality of third holes, and the plurality of fourth holes can be integrally connected with the fine regions disposed between the plurality of fourth holes.

According to the display device of embodiments of the present disclosure, the size of the fine regions can be equal to or less than the size of the plurality of first holes and the plurality of second holes.

According to the display device of embodiments of the present disclosure, the plurality of first holes and the plurality of second holes can have a circular structure, and the width of the fine regions can be equal to or less than the diameter of the plurality of first holes and the plurality of second holes.

According to the display device of embodiments of the present disclosure, the diameter of the second holes can be greater than the diameter of the first holes.

The display device according to embodiments of the present disclosure can further include a black matrix disposed on the encapsulation layer and adjacent to the color filter, wherein the color filter can overlap the plurality of first holes and the plurality of second holes, and the black matrix can overlap the fine regions.

According to the display device of embodiments of the present disclosure, the first bank can include an opaque organic material, the second bank can include a transparent organic material, and the thickness of the first bank can be equal to or greater than the thickness of the second bank.

The display device according to embodiments of the present disclosure can further include a light-emitting layer disposed on the pixel electrode and a common electrode disposed on the light emitting layer, wherein the light-emitting layer can overlap the plurality of first holes, and the common electrode can be disposed to cover the light emitting layer, a side surface of the first bank, a portion of an upper surface of the first bank, and the second bank.

According to embodiments of the present disclosure, a display device can include a plurality of sub-pixels disposed on a substrate and configured to display images, at least one of the plurality of subpixels including a pixel electrode; a first bank disposed on the pixel electrode; a second bank disposed on the first bank; and an encapsulation layer disposed on the second bank, wherein the first bank comprises a plurality of first holes overlapping the pixel electrode, wherein the second bank comprises a plurality of second holes and a fine region, and wherein the encapsulation layer comprises an organic encapsulation layer interposed in the plurality of first holes of the first bank, and the plurality of second holes and the fine region of the second bank.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the technical idea and scope of the present disclosure. The above description and the accompanying drawings provide an example of the technical idea of the present disclosure for illustrative purposes only. For example, the disclosed embodiments are intended to illustrate the scope of the technical idea of the present disclosure.

What is claimed is:

1. A display device comprising:
a substrate;
a pixel electrode disposed on the substrate;
a first bank disposed on the pixel electrode;
a second bank disposed on the first bank;
an encapsulation layer disposed on the second bank; and
a color filter disposed on the encapsulation layer,
wherein the first bank comprises a plurality of first holes overlapping the pixel electrode, and
wherein the second bank comprises a plurality of second holes and a fine region, the plurality of second holes overlapping the plurality of first holes, but the fine region not overlapping the plurality of first holes.

2. The display device according to claim 1,
wherein the encapsulation layer comprises:
a first inorganic encapsulation layer disposed on the first bank and the second bank;
an organic encapsulation layer disposed on the first inorganic encapsulation layer; and
a second inorganic encapsulation layer disposed on the organic encapsulation layer, and
wherein the organic encapsulation layer is interposed in the plurality of first holes, the plurality of second holes, and the fine region.

3. The display device according to claim 2, wherein a thickness of the organic encapsulation layer interposed in the plurality of first holes and the plurality of second holes is equal to or greater than a thickness of the organic encapsulation layer interposed in the fine region.

4. The display device according to claim 2, wherein a height of the organic encapsulation layer in an area where the plurality of first holes and the plurality of second holes overlap is lower than a height of the organic encapsulation layer in an area where the fine region is located.

5. The display device according to claim 1,
wherein the fine region is disposed between the plurality of second holes, and
wherein the fine region and the plurality of second holes are integrally connected to each other.

6. The display device according to claim 5, wherein the fine region and the plurality of second holes that are integrally connected to each other have a mesh shape.

7. The display device according to claim 1,
wherein the fine region is disposed between the plurality of second holes, and
wherein the fine region and the plurality of second holes are spaced apart from each other.

8. The display device according to claim 7, wherein the fine region surrounds an outer circumference of each of the plurality of second holes.

9. The display device according to claim 8, wherein the fine region has a lattice grid shape.

10. The display device according to claim 1,
wherein the plurality of second holes are arranged in a plurality of rows,
wherein the plurality of rows comprise a first row and a second row adjacent to each other, and
wherein the plurality of second holes comprise a plurality of third holes arranged in the first row and a plurality of fourth holes arranged in the second row.

11. The display device according to claim 10, wherein a size of one of the plurality of third holes is different from a size of one of the plurality of fourth holes.

12. The display device according to claim 10, wherein a size of one of the plurality of third holes is the same as a size of one of the plurality of fourth holes.

13. The display device according to claim 10,
wherein the plurality of third holes are integrally connected to the fine region disposed between the plurality of third holes, and
wherein the plurality of fourth holes are integrally connected to the fine region disposed between the plurality of fourth holes.

14. The display device according to claim 1, wherein a size of the fine region is equal to or smaller than a size of one of the plurality of first holes and a size of one of the plurality of second holes.

15. The display device according to claim 1,
wherein the plurality of first holes and the plurality of second holes have a circular structure, and
wherein a width of the fine region is equal to or smaller than a diameter of one of the plurality of first holes and a diameter of one of the plurality of second holes.

16. The display device according to claim 15, wherein a diameter of one of the plurality of second holes is greater than a diameter of one of the plurality of first holes.

17. The display device according to claim 1, further comprising a black matrix disposed on the encapsulation layer and adjacent to the color filter,
wherein the color filter overlaps the plurality of first holes and the plurality of second holes, and
wherein the black matrix overlaps the fine region.

18. The display device according to claim 1,
wherein the first bank comprises an opaque organic material,
wherein the second bank comprises a transparent organic material, and
wherein a thickness of the first bank is equal to or greater than a thickness of the second bank.

19. The display device according to claim 1, further comprising:
a light-emitting layer disposed on the pixel electrode; and
a common electrode disposed on the light-emitting layer,
wherein the light-emitting layer overlaps the plurality of first holes, and
wherein the common electrode is arranged to cover the light-emitting layer, a side surface of the first bank, a portion of an upper surface of the first bank, and the second bank.

20. A display device comprising:
a plurality of sub-pixels disposed on a substrate and configured to display images, at least one of the plurality of subpixels including a pixel electrode;
a first bank disposed on the pixel electrode;
a second bank disposed on the first bank; and
an encapsulation layer disposed on the second bank,
wherein the first bank comprises a plurality of first holes overlapping the pixel electrode,
wherein the second bank comprises a plurality of second holes and a fine region, and
wherein the encapsulation layer comprises an organic encapsulation layer interposed in the plurality of first holes of the first bank, and the plurality of second holes and the fine region of the second bank.
